(19) United States
(12) Patent Application Publication
(10) Pub. No.: US 2007/0008019 A1
(43) Pub. Date: Jan. 11, 2007

(54) Mechanical control elements for organic polymer electronic devices

(76) Inventors: Wolfgang Clemens, Puschendorf (DE); Jurgen Ficker, Erlangen (DE); Alexander Friedrich Knobloch, Erlangen (DE); Andreas Ullmann, Zirndorf (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/570,571

(22) PCT Filed: Aug. 31, 2004
(86) PCT No.: PCT/DE04/01929

§ 371 Date: Mar. 2, 2006

(30) Foreign Application Priority Data
Sep. 3, 2003 (DE) 10340644.0

(51) Int. Cl. H03B 1/00

(52) U.S. Cl. 327/112

(57) ABSTRACT

A switching element for polymer electronic devices is constructed from organic materials.

For any type of electronic devices, the deliberate control of the electronic devices is an important point. In the aborning field of polymer electronic devices, too, this will be necessary and enables entirely new applications for these electronic devices. The electronic devices can be influenced by a mechanical pushbutton element. It is thus possible to switch or to influence electrical signals or material constants.

Taking this as a departure point, the invention is based on the object of providing a maximally cost-effective and compatible switching element for polymer electronic devices.

This object is achieved by means of the inventions specified in the independent claims. Advantageous refinements emerge from the dependent claims.

Accordingly, a switching element, in particular a pushbutton element, for the mechanical switching of polymer electronic devices has conducting and nonconducting organic substances or comprises such substances. The organic substances are polymers, in particular. A combination of organic materials with conventional materials such as metals, for instance, is also possible.

This obviates the interconnection of nonpolymeric pushbutton units with polymeric circuits. By virtue of the polymeric pushbutton or switching element, on the one hand the advantages of polymer electronic devices such as flexibility, cost-effectiveness and printability can be utilized for the switching element itself; on the other hand, however, the major advantage is also afforded that the switching element can be produced together with the electronic devices.

The electronic devices can be influenced permanently, reversibly and temporarily by the mechanical switching element. For this purpose, the switching element can for example be mechanically switched reversibly or irreversibly.

Alternatively or supplementarily, the switching element is a switching element which changes one of its electrical values, in particular its capacitance, analogously, that is to say for example proportionally or logarithmically, with the magnitude of the pressure exerted on the switching element.

In one preferred variant, the switching element has two organic conduction elements situated opposite one another, for example in the form of electrodes and/or contact elements, which are separated by an insulating organic layer having an opening. In particular, one of the two organic conduction elements is then flexible, so that it can be pressed through the opening in the insulating organic layer onto the other organic conduction element. If the conduction element is elastically deformable in this case, then a contact is thereby closed reversibly, that is to say temporarily. If, by contrast, the conduction element is plastically deformable, then the contact is permanently closed.

In another variant, the switching element has three organic conduction elements, of which two are conductively connected by the third and the third can be removed from the first two conduction elements by pressure in order to interrupt the electrical conduction. It is thereby possible to realize a contact which can be disconnected by pressure. For this purpose, the third conduction element may be mounted in resilient fashion or be flexible itself. In the latter case, a reversible or irreversible switching behavior results depending on whether the third conduction element is plastically or elastically deformable.

For a contact that is interrupted by pressure, the switching element may also have an organic conduction element and means by which the conduction element can be interrupted if pressure is exerted on them.

Alternatively or supplementarily, the switching element may have an organic transistor, in particular a field effect transistor, the current of which can be controlled by pressure on the switching element.

In a method for producing a switching element, the latter is embodied with or in conducting and insulating organic substances. Advantageous refinements of the method emerge analogously to the advantageous refinements of the switching element, and vice versa.

Further advantages and features of the invention emerge from the description of an exemplary embodiment with reference to the drawing, in which

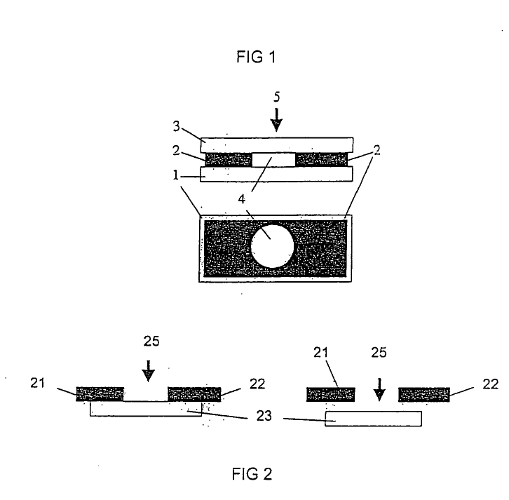

FIG. 1 shows a switching element in the form of a mechanical pushbutton element which can be switched in conducting fashion by pressure;

FIG. 2 shows a switching element in the form of a mechanical pushbutton element which can be switched in nonconducting fashion by pressure;

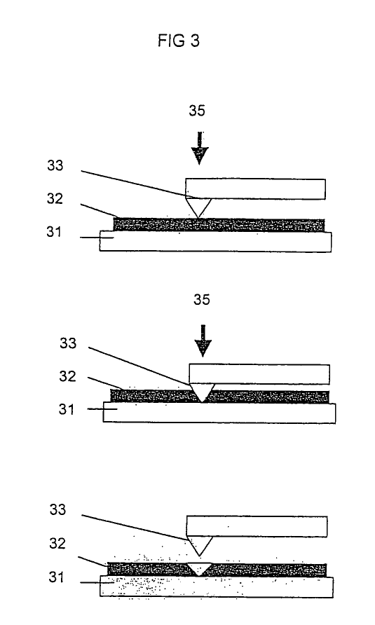

FIG. 3 shows a switching element in the form of a mechanically irreversible pushbutton element which can be switched in nonconducting fashion by pressure;

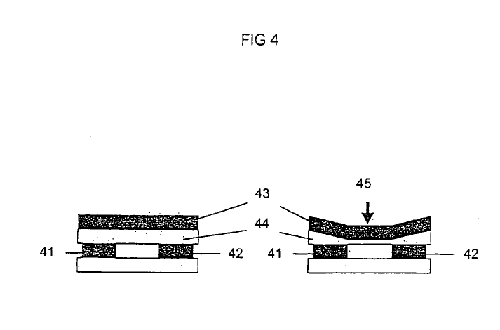

FIG. 4 shows a switching element in the form of a pressure-sensitive pushbutton element in which the pressure exerted on the switching element can be measured.

Organic substances or materials, in particular polymers, are used for the construction of switching elements. Use is preferably made of typical organic materials of polymer electronic devices, such as, for example, conducting, nonconducting, insulating, flexible polymers. The exemplary embodiments can be differentiated into three classes:
a) mechanically reversible pushbutton elements, in the case of which multiple triggering is possible and which exhibits a digital switching behavior;
b) mechanically irreversible pushbutton elements, in the case of which only single triggering is possible and which exhibits a digital switching behavior;
c) pressure-sensitive pushbutton elements having an analog switching behavior.

FIGS. 1 and 2 show examples for class a). FIG. 1 shows two conduction elements 1 and 3 situated opposite one another in the form of electrodes, which are electrically isolated by an insulating layer 2. The conduction elements 1 and 3 are made of a conducting polymer, and the insulating layer 2 is made of a nonconducting polymer. Said layer 2 has a defined opening 4. As soon as a mechanical pressure 5 is exerted on the flexible conduction element 3, an electrical short circuit arises between the conduction elements 1 and 3 and an electric current flows or an electrical signal is passed on. If pressure is exerted by both, both conduction elements 1 and 3 may also be configured in flexible fashion. The pressure required for triggering can be set by way of the thickness of the insulating layer 2 and the size of the opening 4. A repeatable switching behavior is made possible by means of the reversibly elastic behavior of the material of the flexible conduction element 3.

It is likewise possible to reverse the switching behavior, that is to say that a permanent electrical conduction can be disconnected by mechanical pressure. A switching element suitable for this is illustrated in FIG. 2. It has three conduction elements 21, 22, 23 in the form of contacts. The first two conduction elements 21, 22 are connected to one another by the third conduction element 23. As soon as a mechanical pressure 25 is exerted, the third conduction element 23 is removed from the first two conduction elements 21, 22 and the electrical contact is interrupted.

The application of class b) is in turn divided into two possibilities. Firstly it is possible to produce an irreversible conductivity between two electrodes, and secondly an existing conductivity may be interrupted irreversibly. In FIG. 3, a conduction element 32 in the form of an electrical conductor track on a substrate 31 is permanently isolated by means of a mechanical pressure 35 onto a harder polymer part 33. For this purpose, the hardware polymer part 33 has a tip or cutting edge which separates the electrical conductor track 32.

The possibility of permanently producing a conductive connection is identical in construction to the exemplary embodiment of FIG. 1 except that the conductive materials used, in the case of a single connection, hold together permanently and thus produce a short circuit. In addition, the thickness of the insulating layer may be adapted.

Switching elements of class c) are capacitive switches, for example, which change their capacitance as a result of mechanical pressure. FIG. 4 illustrates an organic field effect transistor, the current of which from the source 41 to the drain 42 is controlled by an electric field to the gate electrode 43. The field is dependent on the thickness of the insulator 44, which in turn depends on the mechanical pressure 45 applied to the electrode. This enables an analog switching behavior depending on the pressure. In order to digitize this switching behavior, it is readily possible to connect an organic field effect transistor downstream.

A further embodiment has a construction like that illustrated in FIG. 1, but the insulating layer is embodied in continuous fashion without a hole and such that it can be perforated by pressure. For this purpose, the insulating layer may be embodied as a very thin layer and/or at least one of the conduction elements 2, 3 in the form of layers contains rough particles, such as metal and/or graphite particles, for instance.

Yet another embodiment has a construction like that illustrated in FIG. 1, but the insulating layer contains conductive particles, for instance metal and/or graphite particles, and is preferably embodied in continuous fashion without a hole. A conductive path is then produced by pressure.

Various combinations of the switch types presented are also possible.

Polymeric switching elements or switches can be produced extremely favorably on account of the material and production costs. The materials are themselves flexible and can be applied on large-area, flexible substrates without any problems. A further important point is the possibility afforded for problem-free integration of these switches into organic circuits such as are used in polymer electronic devices. This integration enables completely new applications in polymer electronic devices, such as, for example, all polymers, cost-effective electronic game devices for single use.

1. A printed mechanical polymeric switching device for the mechanical switching of electronic devices, comprising:
a substrate; and
a the mechanical polymeric switching element on the substrate, the element comprising conducting and insulating organic substances applied to the substrate by printing.

2. The printed polymeric switching device as claimed in claim 1, wherein the switching element is arranged to be switched mechanically reversibly.

3. (canceled)

4. The printed polymeric switching device as claimed in claim 1 wherein the switching element exhibits a given electrical parameter value and is arranged to be responsive to an applied pressure which changes the electrical parameter value in response to the magnitude of the pressure exerted on the switching device.

5. The printed polymeric switching device as claimed in claim 1 wherein the switching device includes two organic conduction elements situated opposite one another on the substrate, which conduction elements are separated by an insulating organic layer having an opening.

6. The printed polymeric switching device as claimed in claim 5 wherein one of the organic conduction elements is flexible, so that it can be pressed through the opening in the insulating organic layer onto the other organic conduction element.

7. The printed polymeric switching device as claimed in claim 1 wherein the switching device includes a plurality of organic conduction elements, of which two conduction elements are conductively connected by a third conduction element and the third conduction element is arranged to be removable from the other two conduction elements by applied pressure.

8. The printed polymeric switching device as claimed in claim 1 including an organic conduction element on the substrate and an arrangement on the substrate for interrupting the conduction of the conduction element.

9. The printed polymeric switching device as claimed in claim 1 wherein the switching device includes an organic transistor on the substrate, the current of which is controlled by pressure.

10. The printed polymeric switching device of claim 4 wherein the electrical parameter value is capacitance.

11. A polymeric circuit including a printed polymeric switching device as claimed in claim 2.

12. A polymeric circuit including a printed polymeric switching device as claimed in claim 4.

13. A polymeric circuit including a printed polymeric switching device as claimed in claim 5.

14. A polymeric circuit including a printed polymeric switching device as claimed in claim 6.

15. A polymeric circuit including a printed polymeric switching device as claimed in claim 7.

16. A polymeric circuit including a printed polymeric switching device as claimed in claim 8.

17. A polymeric circuit including a printed polymeric switching device as claimed in claim 9.
